(19) United States
(12) Patent Application Publication
(10) Pub. No.: US 2009/0205706 A1
(43) Pub. Date: Aug. 20, 2009

(54) DYE-SENSITIZED SOLAR CELL

(76) Inventor: Minoru WATANABE, Tokyo (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/356,554

(22) Filed: Jan. 21, 2009

(30) Foreign Application Priority Data
Feb. 15, 2008 (JP) 2008-034531

(51) Int. Cl. H01L 31/04; H01L 31/18

(52) U.S. Cl. 136/252; 438/98

(57) ABSTRACT

A dye-sensitized solar cell having a low cost and a high photoelectric transfer efficiency. Exemplary embodiments include an anode electrode layer contacting at least a part of a solar battery layer, which includes a dye-supporting semiconductor layer and an battery electrolyte layer. An exemplary anode electrode layer includes a plurality of through-extending apertures and is buried in the dye-supporting semiconductor layer at a distance from an anode substrate supporting the dye-supporting semiconductor layer.

### CROSS REFERENCE TO RELATED APPLICATION

This application claims the benefit of Japanese Patent Application No. 2008-034531, filed Feb. 15, 2008, which is incorporated by reference.

### BACKGROUND

The present disclosure relates to solar cells and, more particularly, to dye-sensitized solar cells.

The solar energy falling on the entire earth might be one hundred thousand times the energy consumed all over the world. The research and development of equipment for converting the solar energy resource into electrical energy usable for human beings has a history of more than fifty years. Although typical solar cells are regarded as an ideal energy resource with few environmental loads, the solar cell has not become popular to date. One important reason may be the high cost of power generation. In order to reduce the high cost of power generation, higher photoelectric transfer efficiency and reduced material and production costs may be advantageous. Dye-sensitized solar cells have been attracting attention as a potential solution to the above-mentioned problem.

In order to achieve higher photoelectric transfer efficiency, a structure for widening an absorption wavelength region by stacking more than two layers of dye-supporting semiconductor layers in the dye-sensitized solar cell has been utilized. In addition, in order to stack more than two dye-supporting semiconductor layers, electrodes from titanium oxide (TiO2), etc. of the dye-supporting semiconductor layers need to be thick films. See, e.g., Japanese Patent Application Laid-Open Publication No. 2000-77691, which is incorporated by reference.

### SUMMARY

Exemplary embodiments include a dye-sensitized solar cell having a low cost and a high photoelectric transfer efficiency. In an exemplary embodiment, an anode electrode layer contacts at least a part of a solar battery layer, which includes a dye-supporting semiconductor layer and an battery electrolyte layer. An exemplary anode electrode layer includes a plurality of apertures and is buried in the dye-supporting semiconductor layer at a distance from an anode substrate supporting the dye-supporting semiconductor layer.

In an aspect, a dye-sensitized solar cell may include a solar battery layer including a dye-supporting semiconductor layer and a battery electrolyte layer contacting the dye-supporting semiconductor layer; an anode electrode layer and a cathode electrode layer facing one another at a first distance, each of the anode layer and the cathode layer contacting at least a part of the solar battery layer; an anode substrate for supporting the dye-supporting semiconductor layer; and a cathode substrate for supporting the cathode electrode layer; wherein the anode electrode layer includes a plurality of through-extending apertures and is buried in the dye-supporting semiconductor layer at a second distance from the anode substrate.

In a detailed embodiment, a third distance between the anode electrode layer and the battery electrolyte layer may be less than an electron diffusion length in the dye-supporting semiconductor layer. In a further detailed embodiment, a width of the apertures may be less than the electron diffusion length in the dye-supporting semiconductor layer. In a further detailed embodiment, the apertures may be distributed evenly. In a further detailed embodiment, the dye-sensitized solar cell may include a protective film layer covering the anode electrode layer. In a further detailed embodiment, the anode electrode layer may contact the battery electrode layer.

In a detailed embodiment, a width of the apertures may be less than the electron diffusion length in the dye-supporting semiconductor layer. In a detailed embodiment, the apertures may be distributed evenly. In a detailed embodiment, the dye-sensitized solar cell may include a protective film layer covering the anode electrode layer. In a detailed embodiment, the anode electrode layer may contact the battery electrode layer.

In an aspect, a method for producing a dye-sensitized solar cell may include forming an anode electrode substrate by forming a dye-supporting semiconductor layer on an anode substrate so as to include internally an anode electrode layer having a plurality of apertures, the anode substrate and the plurality of apertures being spaced apart by a distance; forming a cathode electrode substrate by forming a cathode electrode layer on a cathode substrate; attaching the anode electrode substrate and the cathode electrode substrate such that the anode electrode layer and the cathode electrode layer face one another; and injecting a battery electrolyte into a space between the anode electrode substrate and the cathode electrode substrate.

In a detailed embodiment, the step of forming the anode electrode substrate may include forming an oxide semiconductor layer on the anode substrate, forming an electrode film on the oxide semiconductor layer, forming metal interconnections by forming the apertures on the electrode film, and forming an additional oxide semiconductor layer covering the electrode film including the aperture.

In a detailed embodiment, the step of forming the anode electrode substrate may include forming an oxide semiconductor layer on the anode electrode substrate, forming at least one trench associated with an interconnection pattern on the oxide semiconductor layer, and forming an electrode layer in the at least one trench.

### BRIEF DESCRIPTION OF THE DRAWINGS

The detailed description refers to the figures in which:

FIG. 1 is a cross-sectional view of a dye-sensitized solar cell in accordance with a first exemplary embodiment;

FIG. 2 is a plan view of an anode electrode substrate of a dye-sensitized solar cell in accordance with the first exemplary embodiment;

FIGS. 3A-3D are cross-sectional views of a dye-sensitized solar cell in accordance with the first exemplary embodiment in various exemplary production steps;

FIG. 3E is a plan view of a dye-sensitized solar cell in accordance with the first exemplary embodiment in an exemplary production step;

FIGS. 3F-3H are cross-sectional views of a dye-sensitized solar cell in accordance with the first exemplary embodiment in various exemplary production steps;

FIGS. 4A-4E are cross-sectional views of a dye-sensitized solar cell in accordance with the first exemplary embodiment in various exemplary production steps;

FIG. 5 is a cross-sectional view of a dye-sensitized solar cell in accordance with a second exemplary embodiment;

FIG. 6A-6B are cross-sectional views of a dye-sensitized solar cell in accordance with the second exemplary embodiment in various exemplary production steps;

FIG. 6C is a plan view of a dye-sensitized solar cell in accordance with the second exemplary embodiment in an exemplary production step; and

FIGS. 6D-6G are cross-sectional views of a dye-sensitized solar cell in accordance with the second exemplary embodiment in various exemplary production steps.

### DETAILED DESCRIPTION

Exemplary embodiments provide a low-cost, dye-sensitized solar cell with a high photoelectric transfer efficiency and a production method thereof.

The present disclosure contemplates that the thickness of the dye-supporting semiconductor layers depends on the electron diffusion length, and the thickness is around 10 μm. Consequently, even when thick films are formed, it may be difficult to improve the photoelectric transfer efficiency due to energy loss caused by the internal resistance.

The present disclosure contemplates that, as a countermeasure to solve the above-mentioned problem, a structure including conductive parts projected from transparent conductive films is disclosed, according to the Japanese Patent Application Laid-Open Publication No. 2000-77691. In the dye-sensitized solar cell described in the Japanese Patent Application Laid-Open Publication No. 2000-77691, a solar battery layer including a dye-supporting layer and a battery electrolyte layer is contacted by transparent conductive films formed on the two transparent substrates, and conductive parts, which are projected from the transparent conductive films contacting the dye-supporting semiconductor layer to the supporting layer, are formed. According to the above-mentioned configuration, a high photoelectric transfer efficiency can be achieved even when areas of the electrodes using titanium oxide, etc. of the dye-supporting semiconductor layers are increased.

The present disclosure contemplates that, in the dye-sensitized solar cell disclosed in the Japanese Patent Application Laid-Open Publication No. 2000-77691, there is a problem that since the projected parts are formed on the transparent films, the production steps and the production cost increase. The ratio of the production cost of the transparent conductive film to the whole cost of the dye-sensitized solar cell is high, and then there is a problem that a significant cost reduction is impossible as long as the transparent conductive film is used.

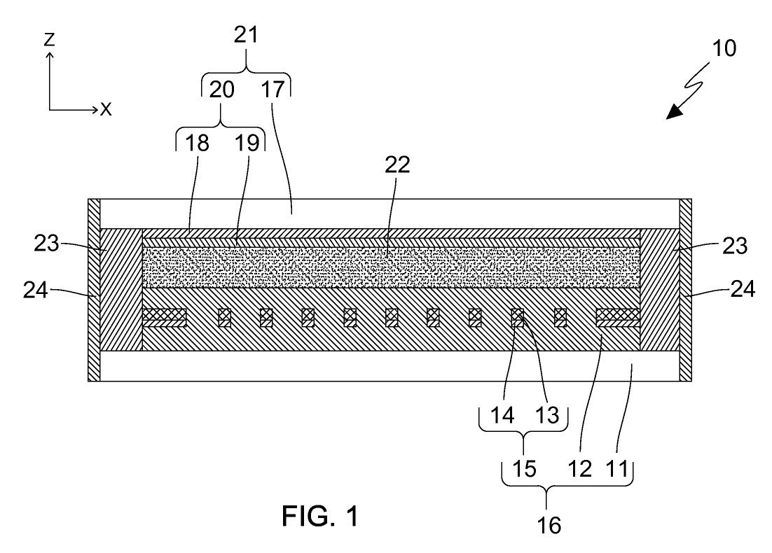

A dye-sensitized solar cell 10 according to a first exemplary embodiment is described with reference to FIG. 1. In the dye-sensitized solar cell 10, a dye-absorbed dye-supporting titanium oxide layer 12 is formed on a transparent glass substrate 11 of an anode substrate. In the dye-supporting titanium oxide layer 12, an anode electrode layer 15, which is composed by a metal thin film 13 and a titanium nitride (TiN) film 14 having a function of an attaching layer for the metal thin film 13, is buried at a distance from the glass substrate 11. An anode electrode substrate 16 includes the glass substrate 11, the dye-supporting titanium oxide layer 12, and the anode electrode layer 15. Furthermore, the anode electrode layer 15 may be covered with a protective film layer (such as titanium film, etc.) to prevent oxidation.

In an exemplary embodiment, a transparent glass substrate 17 of the cathode substrate is placed on an upper part of the glass substrate 11, wherein a fluorine doped tin oxide film 18 (hereinafter referred to as “FTO film 18”) is formed on a surface of the glass substrate 17 (a plane facing the dye-supporting titanium oxide layer 12), and a platinum (“Pt”) film 19 is further formed on the FTO film 18. The FTO film 18 and the Pt film 19 compose a cathode electrode layer 20. The glass substrate 17 and the cathode electrode layer 20 compose a cathode electrode layer 21.

In an exemplary embodiment, a battery electrolyte layer 22 is formed between the anode electrode layer 16 and the cathode electrode substrate 21. The anode electrode layer 16 and a cathode electrode substrate 20 are faced and attached to each other by an adhesive 23. Side faces of the anode electrode substrate 16, the cathode electrode substrate 21, and the adhesive 23 are covered with a plastic sealing layer 24. In the above configuration, the dye-supporting titanium oxide layer 12 and the battery electrolyte layer 22 comprise a solar cell layer.

In an exemplary embodiment, the distance from the anode electrode 15 to the battery electrolyte layer 22 may be less than an electron diffusion length in the dye-supporting titanium oxide layer 12. For example, the distance can be less than approximately 10 μm.

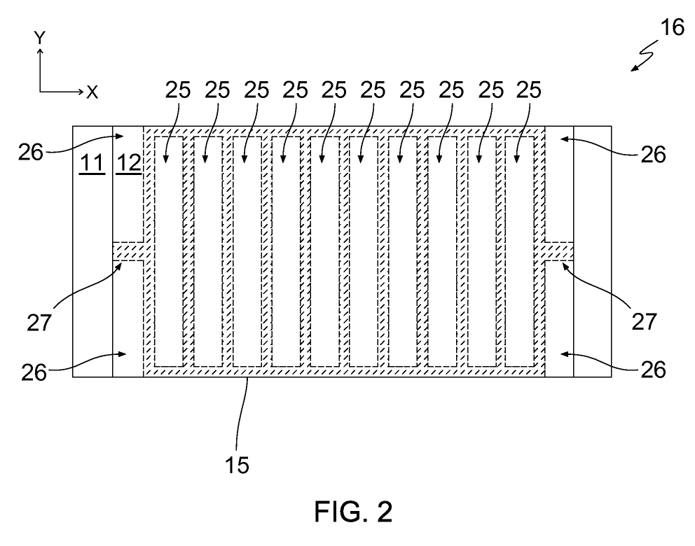

An exemplary shape of the anode electrode layer 15 is described with reference to FIG. 2. In FIG. 2, the portions shown in broken lines are the anode electrode layer 15, and the anode electrode layer 15 includes hole-shaped apertures 25 evenly placed along the X-axis and edge-cut-off apertures 26 placed at both ends of the X-axis. The anode electrode layer 15 has a mesh shape formed by the apertures 25, which are through-extending openings in the anode electrode layer 15. In the above configuration, widths of the apertures 25 can be less than the electron diffusion length in the dye-supporting titanium oxide layer 12, and, for example, the distance can be less than approximately 10 μm.

In an exemplary embodiment, an outgoing electrode unit 27 is formed at both ends of the anode electrode layer 15 along the X-axis using the aperture 26. Since the side plane of the outgoing electrode 27 along the X-axis is exposed, the outgoing electrode unit 27 works as an electrical connection unit of the anode electrode layer 15 to outside the dye-sensitized solar cell 10. For example, without forming the adhesive 23 or the plastic sealing layer 24 on the side plane of the outgoing electrode unit 27, an electrical connection unit can be formed in a part where either of the adhesive 23 or the plastic sealing layer 24 are not formed to achieve electrical connectivity from outside the dye sensitized solar cell 10. Furthermore, even in the case where the adhesive 23 and the plastic sealing layer 24 are formed, pinholes, etc. can be formed as an electrical connection unit to the outgoing electrode unit 27 from the outside.

It is to be understood that the number of the apertures 25 or 26 are not limited to each of the numbers shown in FIG. 2, and the numbers are changed according to the photoelectric transfer efficiency of the dye-sensitized solar cell 10 or the interconnection shape of the outgoing electrode of the dye-sensitized solar cell 10. Also, all of the apertures 25 can be changed to edge-cut-off apertures, and the shape of the anode electrode layer 15 in the X-Y plane can be comb-teeth shape, lattice shape, or honeycomb shape, for example.

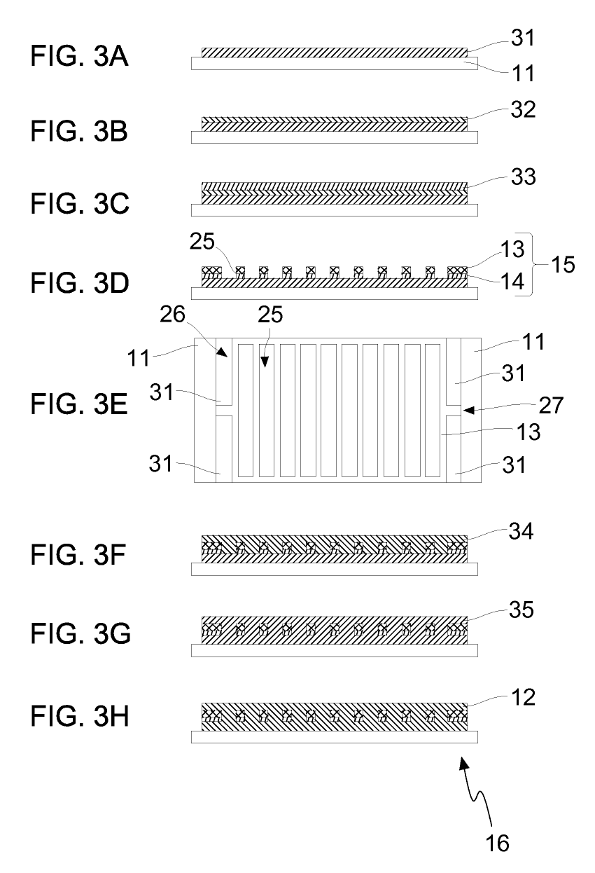

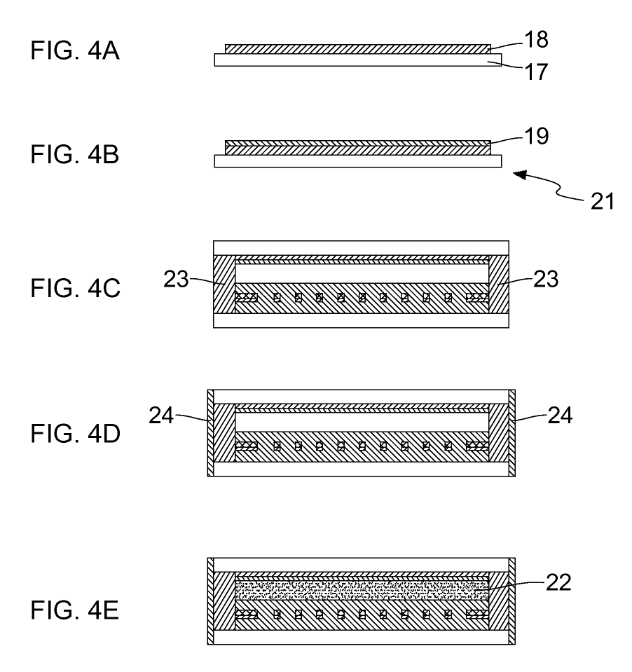

An exemplary method for producing the dye-sensitized solar cell 10 of the first exemplary embodiment is described with reference to FIGS. 3A-3H and 4A-4E. First, a titanium oxide paste is coated on the glass substrate 11 using a screen-printing method to form a titanium oxide layer 31 (FIG. 3A). For example, a coating amount is calculated so that the thickness of the titanium oxide layer 31 becomes approximately 10 μm after baking (i.e., less than the electron diffusion length in the dye-supporting titanium oxide layer 12), and then coating is performed according to the calculated amount. The above-mentioned step is hereinafter referred as an oxide semiconductor layer-forming step.

Next, titanium nitride is deposited on the titanium oxide film layer 31 at approximately a 100 nm thickness to form a titanium nitride layer 32 (FIG. 3B). For example, sputter or chemical vapor deposition (“CVD”), etc. may be used to deposit the titanium nitride. A predetermined metal is deposited on the titanium nitride layer 32 approximately in 800 nm thickness to form a metal thin film 33 (FIG. 3C). As the depositing method, sputter or CVD, etc. can be used, similar to the case of the titanium nitride layer. In addition, metals such as tungsten, iridium, titanium, or nickel, etc., may be used as the predetermined metal. The above-mentioned step is hereinafter referred as a step of forming an electrode film.

Next, an interconnection pattern is transfer-printed using lithography technology to form a resist, and an anode electrode layer 15 is formed as a metal interconnection using dry or wet etching, for example (FIGS. 3D and 3E). For example, the interconnection can be mesh-shaped by forming a plurality of the apertures 25 placed in parallel. In addition, the outgoing electrode unit 27 can be formed by forming a plurality of the apertures 26. The above-mentioned step is hereinafter referred to as a step of forming interconnection. Then, according to need, a protective film can be further formed on the anode electrode layer 15 to prevent oxidation. For example, as the protective film, a titanium film of approximately 10 nm thickness can be used.

Subsequently, additional titanium oxide paste is further coated on the titanium oxide layer 31 and the anode electrode layer 15 by a screen-printing method to form an additional titanium oxide layer 34 (FIG. 3F). By the above-mentioned step, the anode electrode layer 15 is positioned between the titanium oxide layer 31 and the additional titanium oxide layer 34 (i.e., the anode electrode layer 15 is buried in at a distance from the glass substrate 11). In the above step, the additional titanium oxide coating can be performed according to a coating amount to produce the additional titanium oxide layer 34 at approximately 10 μm thickness after baking (i.e., less than the electron diffusion length in the dye-supporting titanium oxide layer 12), similar to the case of the titanium layer 31. The above-mentioned step is hereinafter referred to as a step of forming an additional oxide semiconductor layer.

Subsequently, an ambient atmosphere annealing is performed at around 500° C. for about 90 minutes on the glass substrate 11 where the additional titanium oxide layer 34 has been already formed, to change the titanium oxide layer 32 and the additional titanium layer 34 to a porous titanium oxide layer 35 of around 20 μm thickness (FIG. 3G). After annealing, the porous titanium oxide layer 35 is dipped for about 20 hours in a mixed solution of acetonitrile and t-butyl alcohol in which Ru-type sensitized dye of N719 dye is solved. By the above dipping, the porous titanium oxide layer 35 can be changed to a dye-supporting titanium oxide layer 12 (FIG. 3H). The above-mentioned step can form the anode electrode substrate 16, and the above-mentioned step is hereinafter referred to as a step of forming anode electrode substrate.

Subsequently, an FTO film 18 is formed on an upper plane of the glass substrate 17 (FIG. 4A). Then, Pt is sputtered on the FTO film 18 to form a Pt layer 19 of around 100 Å thickness (FIG. 4B). The above steps form a cathode electrode substrate 21. The above step is hereinafter referred to as a step of forming cathode electrode substrate.

Subsequently, the anode electrode substrate 16 and the cathode substrate 21 are attached to each other by thermo compression bonding using the adhesive 23 such as a HIMILAN film, etc (FIG. 4C). The above step is hereinafter referred to as an attaching step. In the attaching step, the anode electrode layer 15 and the cathode electrode layer 20 are attached to face each other at a predetermined distance.

After attaching the anode electrode substrate 16 and the cathode electrode substrate 21, the anode electrode substrate 16, the cathode electrode substrate 21, and the adhesive 23 are surrounded and sealed by an UV-hardening type sealing plastic to form a sealing plastic layer 24 (FIG. 4D). The above step is hereinafter referred to as a step of sealing.

After sealing, for example, a pinhole is formed in the cathode electrode substrate 21, and battery electrolyte is injected from the pinhole using vacuum injection method. After injecting the battery electrolyte, a battery electrolyte layer 22 is formed by sealing again the pinhole by an epoxy plastic (FIG. 4E). For example, a mixed solution of iodine, lithium iodide, acetonitile, and tributyl phosphate ester (TBP) can be used as the battery electrolyte. The above-mentioned step is hereinafter referred to as a step of battery electrolyte injection.

In addition, in the steps of attaching and sealing, metal contacts, etc. can be formed without forming the adhesive 23 and the plastic sealing layer 24 in a part of the anode electrode layer 15 where the outgoing electrode layer 27 is exposed, so as to provide the anode electrode layer 15 with an electrical connectivity to outside the dye sensitized solar cell 10.

As discussed above, in the dye-sensitized solar cell of the first exemplary embodiment, even when the dye-supporting titanium oxide layer 12 is formed to be a thick film without including high-cost transparent electrode films, since the distance from the anode electrode layer 15 can be made shorter than an electron diffusion length in the dye-supporting titanium oxide layer 12 by burying the anode electrode layer 15 in the dye-supporting titanium oxide layer 12, it becomes possible to provide a low cost solar cell with a high photoelectric transfer efficiency.

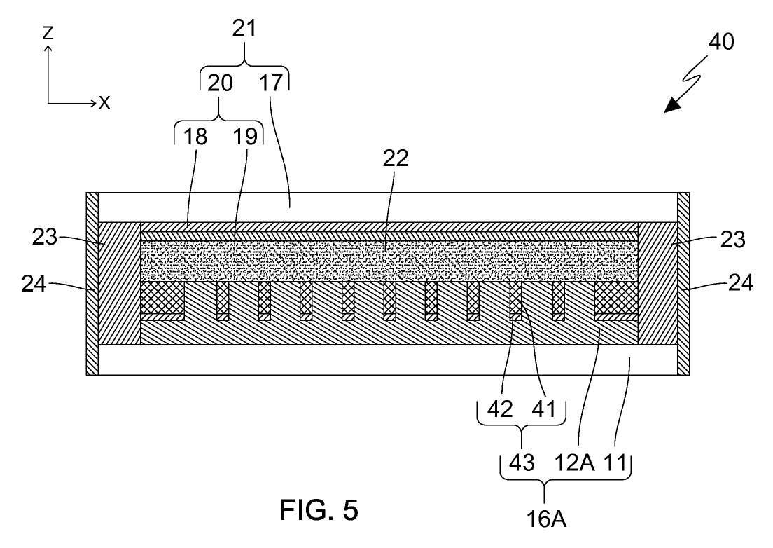

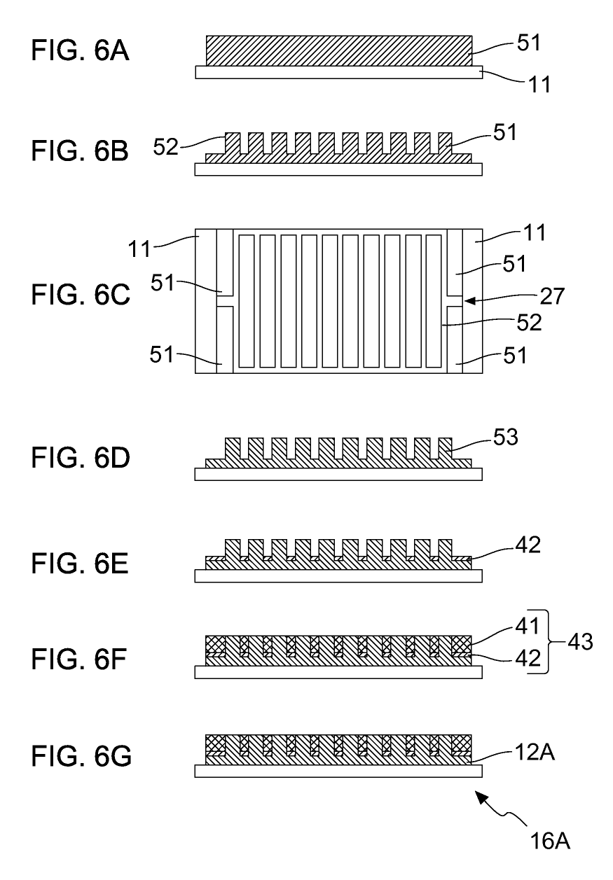

In the dye-sensitized solar cell according to the first exemplary embodiment, the anode electrode layer can be formed to contact the battery electrolyte layer. A second exemplary embodiment of a dye-sensitized solar cell 40 and a production method thereof are described with reference to FIG. 5 and FIG. 6. Elements identical to elements of the first exemplary embodiment are provided with the same numerals as in the first embodiment, and explanations thereof are omitted.

As shown in FIG. 5, an anode electrode layer 43, which is formed with a metal thin film 41 and a titanium nitride (TiN) film 42 having a function of a attaching layer of the metal thin film 41, is buried in the dye-supporting titanium oxide layer 12A in a distance from the glass substrate 11 so as to contact the battery electrolyte 22. In the above configuration, the anode electrode layer 43 can be covered with a protective film (not shown in FIG. 5) such as titanium film, etc.

The anode electrode layer 43 of the dye-sensitized solar cell 40 according to the second exemplary embodiment attaches to the battery electrolyte layer 22 differently from the first exemplary embodiment. Since an electron energized in the battery electrolyte layer 22 can more easily reach to the anode electrode, a higher photoelectric transfer efficiency may be obtained. In addition, even when the dye-supporting titanium oxide layer 12 is formed to be a thick film, since the anode electrode is constantly formed at a location to contact the battery electrolyte layer 22, the dye-supporting titanium oxide layer 12A can be deposited without depending on the electron diffusion length in the dye-supporting titanium oxide layer 12A.

Since the shape of the anode electrode 43 on the X-Y plane is the same as in the first embodiment, explanations thereof will be omitted.

A method of producing the dye-sensitized solar cell 40 according to the second exemplary embodiment is described with reference of FIG. 6. First, titanium oxide paste is coated on the glass substrate 11 using screen printing method to form a titanium oxide layer 51 (FIG. 6A). For example, a coating amount is calculated so that a thickness of the titanium oxide layer 51 becomes approximately 20 μm after baking, and then coating is performed according to the calculated amount. The above-mentioned step is hereinafter referred as a step of forming oxide semiconductor layer.

Subsequently, a press work is performed on the surface of the titanium oxide layer 51 by nanoimprint technology using a mold including predetermined interconnection width and patterns, to form a plurality of trenches 52 on the titanium oxide layer 51 (FIGS. 6B and 6C). The above-mentioned step is hereinafter referred to as a step of forming trench. In addition, baking may be performed at a temperature between 100° C. to 200° C., for example, during the step of forming trench to volatilize solvent, etc. included in the titanium oxide paste.

Subsequently, an ambient atmosphere annealing is performed at around 500° C. for about 90 minutes on the glass substrate 11 where the trenches 52 of interconnections patterns have been already formed to change the titanium oxide layer 51 to a porous titanium oxide layer 53 of around 20 μm thickness (FIG. 6D).

Subsequently, titanium nitride is deposited on the trench 52 in a 10 nm to 100 nm thickness, for example, to form the titanium nitride layer 42 (FIG. 6E). For example, sputter or CVD, etc. can be used as a method for depositing the titanium nitride. A predetermined metal is deposited on the titanium nitride layer 42 in 50 nm to 500 nm thickness to form the metal thin film 41 (FIG. 6F). As a depositing method, sputter or CVD, etc. can be used, similar to the case of the titanium nitride layer. In addition, metals such as tungsten, iridium, titanium, or nickel, etc., may be used as the predetermined metal. The above-mentioned step is hereinafter referred as a step of forming an electrode film. Furthermore, any thickness of the metal thin film 41 can be determined according to the thickness of the porous titanium oxide layer 53. For example, in a condition where the porous titanium oxide layer 53 thickness is around 20 μm and the electron diffusion length is around 10 μm in the porous titanium oxide layer 53, which has been already formed to support the dye, the thickness of the metal thin film 41 may be designed to be around 10 μm.

After annealing, the porous titanium oxide layer 53 is dipped for about 20 hours in a mixed solution of acetonitrile and t-butyl alcohol in which Ru-type sensitized dye of N719 dye is solved. By the above dipping, the porous titanium oxide layer 35 can be changed to the dye-supporting titanium oxide layer 12A (FIG. 6G). The above-mentioned step can form the anode electrode substrate 16A. The above-mentioned step is hereinafter referred to as a step of forming an anode electrode substrate.

Subsequently, the cathode electrode substrate 21 is formed, attached, sealed, and injected with the battery electrolyte, similarly to the first embodiment. Since these steps are generally the same as in the first exemplary embodiment, explanations thereof are omitted.

In addition, a forming method of the trench 51 is not limited to nanoimprint technology. For example, the trench 51 can be formed using a combination of photo-lithography or electron beam (“EB”) lithography technology and dry or wet etching technology.

As explained above, according to the dye-sensitized solar cell of the second exemplary embodiment, even when the dye-supporting titanium oxide layer 12A is formed as a thick film without including high-cost transparent electrode films, since the anode electrode layer 15 is formed in a place where the anode electrode layer 15 contacts the battery electrolyte layer 21, it is possible to provide a low-cost dye-sensitized solar cell with a high photoelectric transfer efficiency.

Additionally, according to the dye-sensitized solar cell of the second exemplary embodiment, it may be possible to obtain an aperture rate (i.e. optical transmittance) higher than in the first exemplary embodiment.

While exemplary embodiments have been set forth above for the purpose of disclosure, modifications of the disclosed embodiments as well as other embodiments thereof may occur to those skilled in the art. Accordingly, it is to be understood that the disclosure is not limited to the above precise embodiments and that changes may be made without departing from the scope. Likewise, it is to be understood that it is not necessary to meet any or all of the stated advantages or objects disclosed herein to fall within the scope of the disclosure, since inherent and/or unforeseen advantages of the may exist even though they may not have been explicitly discussed herein.

What is claimed is:

1. A dye-sensitized solar cell comprising:
a solar battery layer including a dye-supporting semiconductor layer and a battery electrolyte layer contacting the dye-supporting semiconductor layer;
an anode electrode layer and a cathode electrode layer facing one another at a first distance, each of the anode layer and the cathode layer contacting at least a part of the solar battery layer;
an anode substrate for supporting the dye-supporting semiconductor layer; and
a cathode substrate for supporting the cathode electrode layer;
wherein the anode electrode layer includes a plurality of through-extending apertures and is buried in the dye-supporting semiconductor layer at a second distance from the anode substrate.

2. The dye-sensitized solar cell of claim 1, wherein a third distance between the anode electrode layer and the battery electrolyte layer is less than an electron diffusion length in the dye-supporting semiconductor layer.

3. The dye-sensitized solar cell of claim 2, wherein a width of the apertures is less than the electron diffusion length in the dye-supporting semiconductor layer.

4. The dye-sensitized solar cell of claim 3, wherein the apertures are distributed evenly.

5. The dye-sensitized solar cell of claim 4, further comprising: a protective film layer covering the anode electrode layer.

6. The dye-sensitized solar cell of claim 5, wherein the anode electrode layer contacts the battery electrode layer.

7. The dye-sensitized solar cell of claim 1, wherein a width of the apertures is less than the electron diffusion length in the dye-supporting semiconductor layer.

8. The dye-sensitized solar cell of claim 1, wherein the apertures are distributed evenly.

9. The dye-sensitized solar cell of claim 1, further comprising: a protective film layer covering the anode electrode layer.

10. The dye-sensitized solar cell of claim 1, wherein the anode electrode layer contacts the battery electrode layer.

11. A method for producing a dye-sensitized solar cell comprising:
forming an anode electrode substrate by forming a dye-supporting semiconductor layer on an anode substrate so as to include internally an anode electrode layer having a plurality of apertures, the anode substrate and the plurality of apertures being spaced apart by a distance;
forming a cathode electrode substrate by forming a cathode electrode layer on a cathode substrate;
attaching the anode electrode substrate and the cathode electrode substrate such that the anode electrode layer and the cathode electrode layer face one another; and
injecting a battery electrolyte into a space between the anode electrode substrate and the cathode electrode substrate.

12. The method of claim 11, wherein the step of forming the anode electrode substrate includes forming an oxide semiconductor layer on the anode substrate, forming an electrode film on the oxide semiconductor layer, forming metal interconnections by forming the apertures on the electrode film, and forming an additional oxide semiconductor layer covering the electrode film including the aperture.

13. The method of claim 11, wherein the step of forming the anode electrode substrate includes forming an oxide semiconductor layer on the anode electrode substrate, forming at least one trench associated with an interconnection pattern on the oxide semiconductor layer, and forming an electrode layer in the at least one trench.
